(19) United States
(12) Patent Application Publication
(10) Pub. No.: US 2026/0173306 A1
(43) Pub. Date: Jun. 18, 2026

(54) HYBRID LIQUID COOLING SYSTEM INTEGRATING LOW-TEMPERATURE LIQUID METAL CIRCULATION AND LOW-TEMPERATURE COOLANT HEAT DISSIPATION, AND ITS APPLICATIONS

(71) Applicant: Jinyi PAN, Jiaxing (CN)

(72) Inventors: Jinyi PAN, Jiaxing (CN); Jianwu PAN, Jiaxing (CN); Chong ZHANG, Jiaxing (CN); RICHARD PAN, Jiaxing (CN)

(73) Assignee: Jinyi PAN, Jiaxing (CN)

(21) Appl. No.: 19/055,537

(22) Filed: Feb. 18, 2025

(30) Foreign Application Priority Data
Dec. 16, 2024 (CN) 202411854152.8

(51) Int. Cl. H05K 7/20

(52) U.S. Cl. CPC H05K 7/20218

(57) ABSTRACT

A hybrid liquid cooling system that combines low-temperature liquid metal circulation with low-temperature coolant heat dissipation and its application are provided. The hybrid liquid cooling system includes ultra-low melting point liquid metal, heat-absorbing cold plates, flexible transfer pipelines, low-temperature liquid cooling heat dissipation tank, heat dissipation modules, electromagnetic pumps, and together with central cooling system. The hybrid liquid metal cooling system has the following advantages: rapid heat dissipation, excellent thermal conductivity, noise-free operation, flexible structure, scalability, energy efficiency and cost-effectiveness.

### CROSS REFERENCE TO THE RELATED APPLICATIONS

This application is based upon and claims priority to Chinese Patent Application No. 202411854152.8, filed on Dec. 16, 2024, the entire contents of which are incorporated herein by reference.

### TECHNICAL FIELD

The present invention relates to the technical field of heat dissipation systems for high-heat devices, particularly to the high condensed GPU chassis and high power server, by using advanced hybrid liquid cooling system that integrating low-temperature liquid metal circulation with low-temperature coolant heat dissipation and its application.

### BACKGROUND

Rapid heat dissipation is of critical importance in various electronic devices and industrial applications. As modern technology advances, the performance and power density of devices continue to increase, resulting in greater heat generation. Without effective heat dissipation measures, excessive temperature can severely impact device performance, reliability, and lifespan. High-heat devices (such as CPUs, GPUs, smartphones, electric vehicles, nuclear power systems, aerospace systems, etc.) generate significant heat during operation. If the heat cannot be dissipated quickly, the device temperature rises rapidly, causing components to operate in high temperature ranges, resulting in performance degradation, system throttling, or even complete failure. For example, in computing devices, overheating may cause processors to throttle down or reduce operating speeds to prevent damage or trigger self-protection mechanisms, ultimately affecting the overall performance of the device. Therefore, rapid heat dissipation helps maintain long-term stable operation, preventing performance decline.

As technology advances, device sizes are shrinking, but the required processing power and power density continue to rise. This means that heat generation is more concentrated in limited spaces, and traditional cooling methods are increasingly unable to meet these demands. Without an effective rapid heat dissipation mechanism, devices will be limited in their applications due to heat accumulation. Rapid cooling technologies can solve this problem, enabling higher power density and better performance in compact devices.

Long-term high-temperature operation accelerates the aging of electronic components and materials, especially in precision components such as semiconductors (e.g., high-performance GPUs), PCBs, and connectors. Thermal stress causes materials to expand and contract repeatedly, increasing the risk of physical damage. Rapid cooling can effectively slow this aging process, reduce the damage caused by thermal stress, and thus extend the service life of the device. Operating in high-temperature environments often leads to efficiency loss and increased energy waste. In particular, in applications like data centers, nuclear power systems, aerospace launchers, and electric vehicles, excessive temperatures result in significant energy losses. Rapid heat dissipation technologies can more efficiently manage internal temperatures, reducing energy consumption due to temperature rise, thus improving overall energy efficiency.

Traditional cooling methods (such as air cooling, water cooling, and coolant-based liquid cooling) often fail to meet the speed and efficiency requirements. Liquid metals have thermal conductivity 60-80 times higher than water or other coolants. Through liquid metal circulation, high heat can be quickly absorbed and carried away from the heat source. New liquid metal materials, optimized by improved formulations and innovative manufacturing processes, could be remained fluid even at −10° C. and have a boiling point as high as 2400° C. In the cooling cycle, the liquid metal can rapidly transfer high-temperature heat to a low-temperature environment. Therefore, the research and development of a hybrid liquid cooling system combining low-temperature liquid metal circulation with low-temperature coolant heat dissipation is of great significance.

### SUMMARY

The object of the present invention is to overcome the deficiencies of the prior art and provide a hybrid liquid cooling system integrating low-temperature liquid metal circulation with low-temperature coolant heat dissipation, and its application.

To achieve the above object, the present invention provides the following technical solution:

The invention provides a hybrid liquid cooling system integrating low-temperature liquid metal circulation with low-temperature coolant heat dissipation, where the system includes ultra-low melting point liquid metal, heat-absorbing cold plates (1), stainless steel corrugated tubes (3, 5), low-temperature liquid cooling tank (8), heat dissipation modules, electromagnetic pumps (11), and a central cooling system connections (9, 13).

Preferred Embodiment: The ultra-low melting point liquid metal is vacuum-sealed in the heat-absorbing cold plates, and the cold plates are attached to the high-heat device; The ultra-low melting point liquid metal is a gallium-indium-tin alloy with rare earth elements, which maintains fluidity at −10° C. The thermal conductivity of the ultra-low melting point liquid metal is 60-80 times that of water or other coolants.

Preferred Embodiment: The material of the heat-absorbing cold plates and heat dissipation modules is nickel-plated high thermal conductivity metal; the heat-absorbing cold plates include an inlet (2), an outlet (15), and a separator plate (16).

Preferred Embodiment: The flexible transfer pipelines are made of stainless corrugated tubes or other flexible materials resistant to corrosion by liquid metals.

Preferred Embodiment: The heat dissipation module includes heat dissipation copper tubes (7, 14), heat dissipation fins (10), electromagnetic pumps (11), liquid metal inlets (12), and flanges (18).

Preferred Embodiment: The low-temperature liquid cooling tank includes liquid outlets and inlets (9, 13), used to connect to the central cooling system; the electromagnetic pump includes a stainless steel tube (17) in the pump center.

Preferred Embodiment: The ultra-low melting point liquid metal is driven by the electromagnetic force of the electromagnetic pump and flows through the flexible transfer pipelines to the heat-absorbing cold plates.

Preferred Embodiment: The hybrid liquid cooling system is in a fully sealed vacuum state.

Preferred Embodiment: The hybrid liquid cooling system includes a two-stage circulation heat dissipation system. The second-stage circulation system consists of a liquid metal cooling system and a low-temperature coolant for heat dissipation of the liquid metal, while the first-stage circulation system is the heat dissipation cycle formed by the cooling tank and the central cooling system.

The present invention also provides the application of the hybrid liquid cooling system combining low-temperature liquid metal circulation with low-temperature coolant heat dissipation in high-power chips, high-performance computing systems, power electronic devices, nuclear power equipment, and aerospace devices.

### Advantages of the Invention

The hybrid liquid cooling system of the present invention has the following advantages:

Rapid heat dissipation: The two-stage circulation heat dissipation system efficiently transfers heat from high-heat devices to the central cooling system, achieving outstanding heat dissipation performance.

Excellent thermal conductivity: The thermal conductivity of liquid metal is 60-80 times that of water or other coolants, significantly reducing thermal resistance. It is especially suitable for efficient heat dissipation needs of small, high-power chips.

Noise-free operation: The liquid metal cooling system contains no mechanical parts, ensuring silent operation, enhancing user experience, and improving system reliability.

Flexible structure: The system can be configured to cool single or multiple chips and adapt to different device layouts and requirements.

Scalability: The system is highly scalable and suitable for multiple application scenarios, such as high-performance GPUs, servers, nuclear equipment, and aerospace devices.

Energy efficiency and cost-effectiveness: Compared to traditional systems based on water cooling, coolant-based cooling, or air cooling, the hybrid liquid metal cooling system significantly saves energy and reduces operational costs. The system can operate in extremely low-temperature environments while maintaining high efficiency, stability, flexibility, and low cost, providing a reliable thermal management solution for high power density devices.

### BRIEF DESCRIPTION OF THE DRAWINGS

FIG. 1: Schematic diagram of the hybrid liquid cooling system of the present invention used for single-chip or dual-chip heat dissipation devices.

FIG. 2: Schematic diagram of the heat-absorbing cold plate containing liquid metal in the present invention.

FIG. 3: Schematic diagram of the stainless steel corrugated tubes in the present invention.

FIG. 4: Schematic diagram of the low-temperature liquid cooling tank in the present invention.

FIG. 5: Schematic diagram of the heat dissipation module in the present invention.

FIG. 6: Schematic diagram of the electromagnetic pump in the present invention.

FIG. 7: Schematic diagram of the connection between the low-temperature liquid cooling tank and the central cooling system's circulation device.

FIG. 8: Schematic diagram of the liquid metal cooling system for eight high-power chips.

Where:
1: Heat-absorbing cold plate
2: Heat-absorbing cold plate inlet
3, 5: Flexible transfer pipelines
4: Diverting valve
6: Joint between the heat dissipation copper tube and the flexible transfer pipeline
7, 14: Heat dissipation copper tubes
8: Low-temperature heat dissipation coolant tank
9: Liquid inlet to central cooling system
13: Liquid outlet to central cooling system
10: Heat dissipation fins
11: Electromagnetic pump
12: Liquid metal inlet
15: Heat-absorbing cold plate outlet
16: Internal separator plate of the heat-absorbing cold plate
17: Stainless steel tube at the center of the electromagnetic pump
18: Flange
19: Transmission pipeline of the central cooling system

### DETAILED DESCRIPTION OF THE EMBODIMENTS

The present invention provides a hybrid liquid cooling system that combines low-temperature liquid metal circulation with low-temperature coolant heat dissipation. The system includes ultra-low melting point liquid metal, heat-absorbing cold plates (1), flexible transfer pipelines (3, 5), low-temperature liquid cooling tank (8), heat dissipation modules, electromagnetic pumps (11), and the central cooling system.

In this invention, ultra-low melting point liquid metal is vacuum-sealed in the heat-absorbing cold plate, which is attached to a high-power device. The ultra-low melting point liquid metal is preferably a gallium-indium-tin alloy combined with rare-earth elements. It remains liquid even at −10° C., and its thermal conductivity is 60 to 80 times that of water or other coolants, enabling rapid heat transfer from the heat source.

The ultra-low melting point liquid metal used in this invention has excellent thermal conductivity. Liquid metals such as the gallium-indium-tin alloy have thermal conductivities dozens higher than water or coolants. For example, water has a thermal conductivity of 0.59 W/m·K, other coolants range from 0.13 to 0.45 W/m·K, while gallium-based liquid metals have a thermal conductivity of 27-37 W/m·K, which is 60 to 80 times that of water or other coolants. The ultra-low melting point liquid metal also maintains excellent flowability at sub-zero temperatures, allowing it to efficiently transfer heat from high-heat devices to a larger heat dissipation system. Water or other coolants are used as the secondary medium for heat dissipation. The ultra-low melting point liquid metal remains fluid at −10° C., enabling fast and efficient heat dissipation.

When the heat-absorbing cold plate is attached to high-power chips, liquid metal thermal paste or graphene sheet is applied to ensure tight contact. The liquid metal thermal paste is made from low-melting-point metal alloys such as gallium and indium.

The heat-absorbing cold plate and the heat dissipation module are preferably made of high thermal conductivity metals, such as nickel-plated copper. The thermal conductivity of these materials can reach 400 W/m·K. Since liquid metal has some corrosive properties towards high-conductivity metals, the heat-absorbing cold plate and heat dissipation copper pipes are coated with a nickel layer to prevent corrosion and extend their lifespan.

The internal separator plate in the heat-absorbing cold plate ensures that the liquid metal circulates effectively within the cold plate, allowing efficient heat absorption and transferring heat from the high-heat device to the liquid metal. The heated liquid metal is then discharged from the heat-absorbing cold plate outlet (15) and returned to the low-temperature liquid cooling tank via a flexible stainless-steel corrugated pipe.

The flexible transfer pipeline is preferably made of stainless steel corrugated tubing or other materials resistant to liquid metal corrosion. The corrugated structure allows the heat-absorbing cold plate to be positioned flexibly and easily adapt to different installation locations.

The heat dissipation module preferably includes copper tubes (7, 14), heat dissipation fins (10), an electromagnetic pump (11), a liquid metal inlet (12), and flanges (18). The copper tubes are used for efficient heat conduction, while the heat dissipation fins increase the surface area to enhance cooling efficiency. The electromagnetic pump drives the liquid metal flow, ensuring continuous circulation. The liquid metal inlet makes it easy to add or replace the liquid metal, and the flanges are used to connect and secure the components.

The low-temperature liquid cooling tank preferably includes a liquid inlet (9) and a liquid outlet (13), which connect to the central cooling system. The electromagnetic pump preferably includes a stainless-steel central tube (17). The low-temperature liquid cooling tank is used for the heat dissipation of the liquid metal, and the temperature of the coolant inside the tank could be maintained below 0° C. to maximize the temperature gradient and improve the cooling performance. The stainless-steel tube in the center of the electromagnetic pump helps push the liquid metal flow, without any mechanical moving parts, ensuring noiseless and efficient operation. This design effectively avoids the wear problems typical of conventional pumps while improving the reliability and longevity of the system.

The ultra-low melting point liquid metal is preferably driven by the electromagnetic pump's electromagnetic force through the flexible transfer pipe to the heat-absorbing cold plate.

The hybrid liquid cooling system is preferably in a fully sealed vacuum state to prevent the liquid metal from oxidizing and to ensure its long-term flowability.

The central stainless-steel tube of the electromagnetic pump connects to the heat dissipation copper tube through a highly sealed flanges, while the corrugated stainless-steel pipe and the heat dissipation copper tube joint are connected via a sealed sleeve to ensure the liquid metal remains in a vacuum-protected state.

The hybrid liquid cooling system preferably includes a two-stage circulation heat dissipation system. The second-stage circulation system consists of the liquid metal heat dissipation system and the low-temperature coolant heat dissipation system, while the first-stage circulation system is formed by the low-temperature liquid cooling tank and the central cooling system.

Second-stage circulation system: low-temperature liquid metal absorbs heat from the high-heat device (such as GPUs and CPUs) through the heat-absorbing cold plate. The heated liquid metal is driven by the electromagnetic pump through flexible transfer pipelines to the heat dissipation module, where it exchanges heat with the coolant (water or other coolants) in the low-temperature liquid cooling tank, rapidly cooling the liquid metal. The cooled liquid metal is then returned to the high-heat device via the electromagnetic pump, forming a continuous cooling loop.

First-stage circulation system: The heat from the low-temperature liquid cooling tank is transferred to the central cooling system via the inlet and outlet of the low-temperature liquid cooling tank, allowing for broad-area heat dissipation and ensuring the continuity of the cooling cycle and the uninterrupted heat dissipation process. The low-temperature liquid cooling tank connects to the central cooling system, which has integration capabilities.

Through the integration of the two-stage circulation heat dissipation system, the hybrid liquid cooling system significantly improves heat dissipation efficiency and achieves more efficient thermal management. This system is suitable for high-power, high-heat-density devices, ensuring long-term stable operation and greatly enhancing cooling performance.

In this invention, the liquid metal, with its excellent thermal conductivity, rapidly cools in the low-temperature liquid cooling tank, maintaining efficient heat transfer throughout the entire cooling cycle. The two-stage circulation heat dissipation system provides extended cooling capacity, allowing the system to handle larger heat loads, such as multi-chip high-heat devices or high-heat-density units in industrial applications. Through optimized component design and fluid management methods, this invention achieves excellent thermal management performance, making it particularly suitable for high-power, high-heat-density devices and systems.

### Applications of the Invention

This hybrid liquid cooling system, which combines low-temperature liquid metal circulation with low-temperature coolant heat dissipation, is applicable in various fields, including high-power chips, high-performance computing systems, power electronics, nuclear power equipment, and aerospace devices.

High-performance computing systems: These include data centers, GPU servers, or workstations, which require efficient cooling for high-power processors to ensure stable operation.

Power electronics: These include high-power modules, transformers, or electric vehicle batteries (such as lithium-nickel-cobalt-manganese batteries or lithium iron phosphate batteries), providing thermal stability support to extend the lifespan of equipment.

Nuclear power equipment: The system improves the operational stability of critical systems and optimizes thermal management to handle high-temperature challenges.

Aerospace devices: The system efficiently addresses extreme heat requirements in closed, high-stress environments, providing reliable thermal management solutions for aerospace equipment.

By adapting to the needs of different fields, the hybrid liquid cooling system demonstrates exceptional flexibility and efficiency, offering a new solution for heat dissipation in various high-heat-density applications.

### EXAMPLE 1

A hybrid liquid cooling system combining low-temperature liquid metal circulation with low-temperature coolant heat dissipation through a two-stage circulation heat dissipation system is presented. The system operates in a fully sealed vacuum state.

### System Components

Ultra-low melting point liquid metal: The system uses gallium-indium-tin alloy (Ga68.5—In21.5—Sn10), which is vacuum-sealed in a heat-absorbing cold plate.

Heat-absorbing cold plate: This is attached to high-power chips (e.g., NVIDIA GB200) and includes an inlet, outlet, and separator plate.

Materials: The heat-absorbing cold plate and heat dissipation module are made of nickel-plated copper, while the flexible transfer pipeline is a stainless-steel corrugated tube.

Heat dissipation module: Includes copper pipes, heat dissipation fins, an electromagnetic pump, a liquid metal inlet, and a flange.

Low-temperature liquid cooling tank: Contains liquid inlets and outlets, connected to a central cooling system.

Electromagnetic pump: The pump's central pipe is made of stainless steel, and it is connected to the heat dissipation copper pipes through highly sealed flanges. The stainless-steel corrugated pipe is connected to the copper pipes via sealed joints.

### Second-Stage Circulation Heat Dissipation System

The heat-absorbing cold plate, which contains ultra-low melting point liquid metal, is directly attached to high-power chips. Liquid metal thermal paste (made from gallium and indium) is applied between the cold plate and the chip for better thermal contact.

Heat from the high-power chip is transferred to the ultra-low melting point liquid metal inside the heat-absorbing cold plate. The liquid metal is circulated through a closed-loop flexible transfer pipe, driven by the electromagnetic pump. The heated liquid metal is then quickly transported to the heat dissipation module, which is immersed in the low-temperature liquid cooling tank (containing low-temperature water or coolant).

The heat collected by the liquid metal is transferred via copper pipes to the water in the low-temperature liquid cooling tank, where the metal cools down. The cooled liquid metal is then driven back to the heat-absorbing cold plate via the electromagnetic pump, forming a continuous cooling loop.

### First-Stage Circulation Heat Dissipation System

After the liquid metal heats up the water or coolant in the low-temperature liquid cooling tank, the heated water or coolant is transported through the low-temperature liquid cooling tank's inlets and outlets to the central cooling system. This transfers the heat to the central cooling system, enabling large-scale heat dissipation.

The cooled water is then returned to the low-temperature liquid cooling tank via a pressurizing pump in the central cooling system, maintaining the low temperature in the liquid cooling tank and ensuring efficient cooling.

### EXAMPLE 2

In this example, the high-power chip from Example 1 is replaced by a GPU chip, while the other conditions remain the same as in Example 1.

### EXAMPLE 3

In this example, the high-power chip from Example 1 is replaced by a power battery (such as a lithium iron phosphate battery), with all other conditions remaining the same as in Example 1.

### Conclusion

The examples above are preferred embodiments of the invention. It should be noted that, for ordinary skilled persons in this technical field, various modifications and refinements can be made without departing from the principles of the invention. These modifications and refinements are also considered within the scope of the invention's protection.

### DESCRIPTION OF THE DRAWINGS

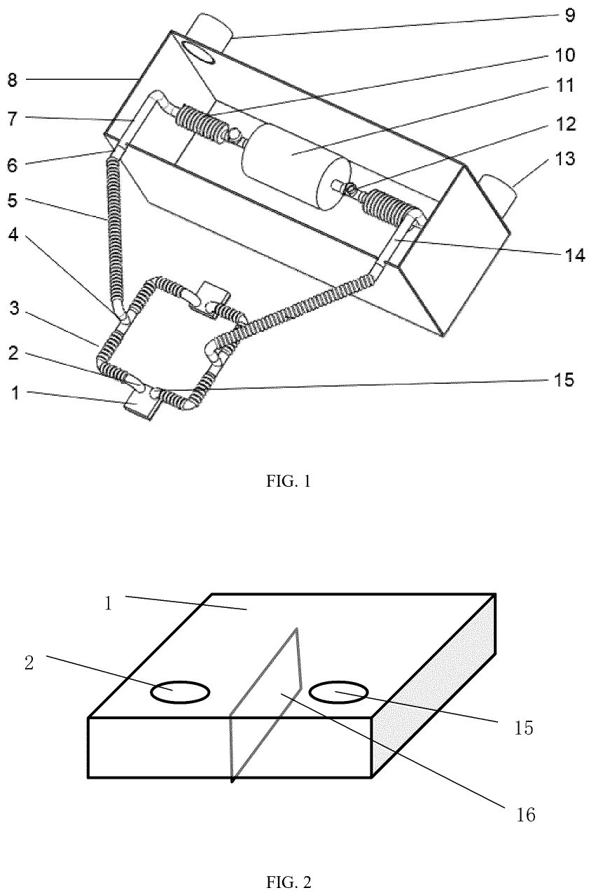

FIG. 1—Schematic of the Hybrid Liquid Cooling System for Single or Dual Chip Cooling Devices: This figure illustrates how the hybrid liquid cooling system works in high-power devices (such as single or dual chips). It shows the connections between components like the heat-absorbing cold plate, flexible transfer pipelines, low-temperature liquid cooling tank, and heat dissipation modules, as well as the flow path of the liquid metal and its heat exchange with low-temperature coolant.

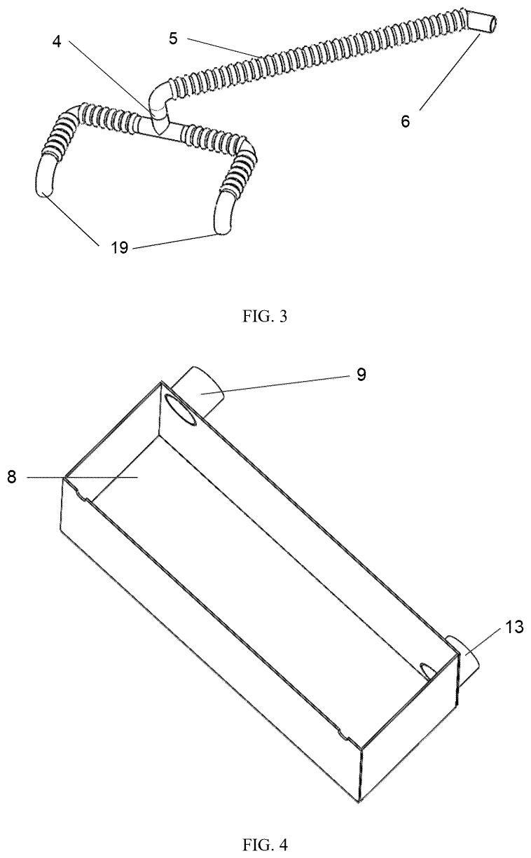

FIG. 2—Schematic of the Heat-Absorbing Cold Plate Containing Liquid Metal: This figure shows the internal structure of the heat-absorbing cold plate, how the liquid metal is encapsulated inside, and how it makes contact with high-heat devices (such as CPUs or GPUs). The figure highlights the inlet, outlet, and isolation plate of the heat-absorbing cold plate, as well as its connection with high-heat devices.

FIG. 3—Schematic of the Flexible Transfer Pipeline: This figure depicts the structure of the flexible transfer pipeline, typically made of stainless steel corrugated tubing or other materials resistant to corrosion by liquid metal. It clearly shows how the flexible pipelines connect with other parts of the heat dissipation system and how liquid metal flows through these pipelines.

FIG. 4—Schematic of the Low-Temperature Liquid Cooling Tank: This figure illustrates the internal structure of the low-temperature liquid cooling tank, including the liquid inlet and outlet, and how it connects with the central cooling system to form the second-stage heat dissipation loop. It also shows the flow path of the cooling liquid and how it exchanges heat with the liquid metal for dissipation.

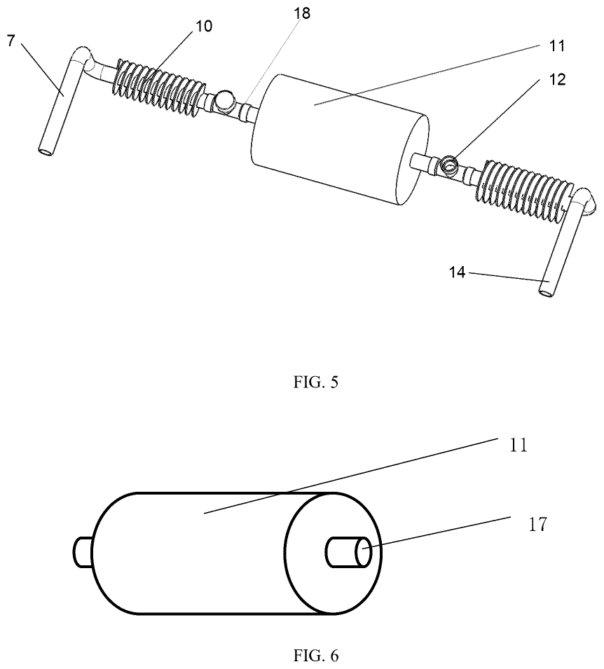

FIG. 5—Schematic of the Heat Dissipation Module: This figure shows the components of the heat dissipation module, including the heat dissipation copper pipes, cooling fins, electromagnetic pump, liquid metal injection port, and flange. The figure highlights how the liquid metal undergoes heat exchange within the module, transferring the heat to the low-temperature coolant.

FIG. 6—Schematic of the Electromagnetic Pump: This figure illustrates the design of the electromagnetic pump, focusing on its central stainless steel pipe and how it uses electromagnetic force to drive the flow of liquid metal. It shows the installation of the pump and its connections with flexible transfer pipelines and other system components.

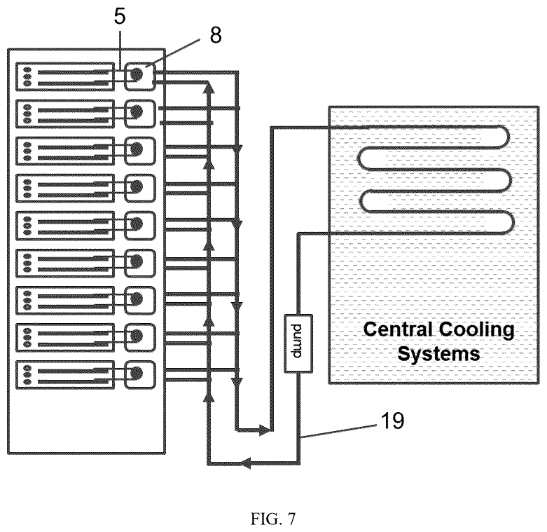

FIG. 7—Schematic of the Connection Between the Low-Temperature Liquid Cooling Tank and the Central Cooling System: This figure shows how the low-temperature liquid cooling tank connects with the central cooling system. After heat exchange in the low-temperature liquid cooling tank, the heated water is transferred via connecting pipes to the central cooling system, where it dissipates heat. The cooled water is then returned to the low-temperature liquid cooling tank, ensuring the cooling liquid remains at a low temperature.

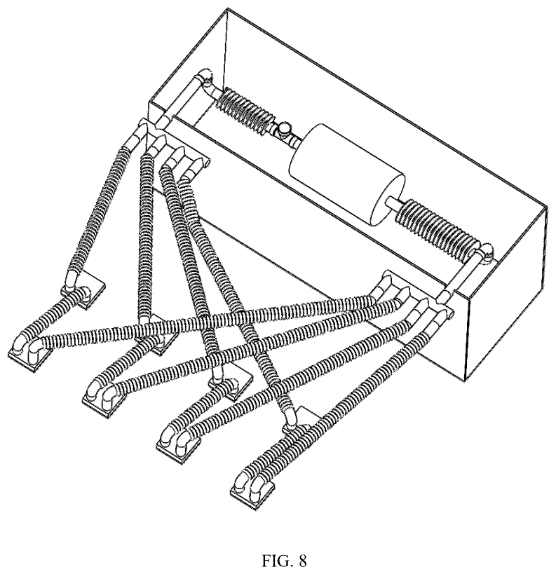

FIG. 8—Schematic of the Liquid Metal Cooling System for Eight High-Power Chips: This figure shows a more complex application scenario where the liquid metal cooling system is used to dissipate heat from multiple high-power chips (such as a GPU cluster). It demonstrates how multiple heat-absorbing cold plates, flexible pipelines, and heat dissipation modules work together to achieve efficient cooling. This schematic highlights the scalability of the system for multi-chip, high-heat density devices.

### KEY COMPONENTS IN THE DRAWINGS

1: Heat-absorbing cold plate
2: Heat-absorbing cold plate inlet
3, 5: Flexible transfer pipeline
4: Shunt valve
6: Heat dissipation copper pipe and flexible transfer pipeline joint
7, 14: Heat dissipation copper pipes
8: Low-temperature liquid cooling tank
9: Liquid inlet of the low-temperature liquid cooling tank to the central cooling system
13: Liquid outlet of the low-temperature liquid cooling tank to the central cooling system
10: Heat dissipation fins
11: Electromagnetic pump
12: Liquid metal injection port
15: Heat-absorbing cold plate outlet
16: Internal seperate plate of the heat-absorbing cold plate
17: Central stainless steel pipe of the electromagnetic pump
18: Flange
19: Transmission pipeline of the central cooling system

What is claimed is:

1. A hybrid liquid cooling system combining low-temperature liquid metal circulation with low-temperature coolant heat dissipation, comprising an ultra-low melting point liquid metal, a heat-absorbing cold plate, flexible transfer pipelines, a low-temperature liquid cooling tank, a heat dissipation module, an electromagnetic pump, and a central cooling system.

2. The hybrid liquid cooling system according to claim 1, wherein the ultra-low melting point liquid metal is vacuum-sealed in the heat-absorbing cold plate, and the heat-absorbing cold plate is attached to a high-heat device;
the ultra-low melting point liquid metal is a gallium-indium-tin alloy with rare earth elements, prepared to maintain fluidity at −10°C; a thermal conductivity of the ultra-low melting point liquid metal is 50 to 80 times a thermal conductivity of water or other coolants.

3. The hybrid liquid cooling system according to claim 1, wherein a material of the heat-absorbing cold plate and heat dissipation module is a nickel-plated high thermal conductivity metal; the heat-absorbing cold plate comprises a heat-absorbing cold plate inlet, a heat-absorbing cold plate outlet, and a separator plate.

4. The hybrid liquid cooling system according to claim 3, wherein the flexible transfer pipelines are stainless steel corrugated tubes or made of other materials resistant to corrosion by liquid metals.

5. The hybrid liquid cooling system according to claim 3, wherein the heat dissipation module comprises heat dissipation copper tubes, heat dissipation fins, the electromagnetic pump, a liquid metal inlet, and flanges.

6. The hybrid liquid cooling system according to claim 4, wherein the low-temperature liquid cooling tank comprises liquid outlets and inlets configured to connect to the central cooling system; the electromagnetic pump comprises an electromagnetic pump center stainless steel tube.

7. The hybrid liquid cooling system according to claim 6, wherein the ultra-low melting point liquid metal is driven by an electromagnetic force of the electromagnetic pump and flows through the flexible transfer pipelines to the heat-absorbing cold plate.

8. The hybrid liquid cooling system according to claim 7, wherein the hybrid liquid cooling system is in a fully sealed vacuum state.

9. The hybrid liquid cooling system according to claim 1, further comprising a two-stage circulation heat dissipation system, wherein a second-stage circulation heat dissipation system is composed of a liquid metal heat dissipation system and a low-temperature coolant heat dissipation system, and a first-stage circulation heat dissipation system is a heat dissipation cycle formed by the low-temperature liquid cooling tank and the central cooling system.

10. The hybrid liquid cooling system according to claim 1, wherein the hybrid liquid cooling system is applied in high-power chips, high-performance computing systems, power electronic devices, nuclear power equipment, and aerospace devices.

11. The hybrid liquid cooling system according to claim 2, wherein a material of the heat-absorbing cold plate and heat dissipation module is a nickel-plated high thermal conductivity metal; the heat-absorbing cold plate comprises a heat-absorbing cold plate inlet, a heat-absorbing cold plate outlet, and a separator plate.

12. The hybrid liquid cooling system according to claim 5, wherein the low-temperature liquid cooling tank comprises liquid outlets and inlets configured to connect to the central cooling system; the electromagnetic pump comprises an electromagnetic pump center stainless steel tube.

13. The hybrid liquid cooling system according to claim 8, further comprising a two-stage circulation heat dissipation system, wherein a second-stage circulation heat dissipation system is composed of a liquid metal heat dissipation system and a low-temperature coolant heat dissipation system, and a first-stage circulation heat dissipation system is a heat dissipation cycle formed by the low-temperature liquid cooling tank and the central cooling system.

14. The hybrid liquid cooling system according to claim 2, wherein the hybrid liquid cooling system is applied in high-power chips, high-performance computing systems, power electronic devices, nuclear power equipment, and aerospace devices.

15. The hybrid liquid cooling system according to claim 3, wherein the hybrid liquid cooling system is applied in high-power chips, high-performance computing systems, power electronic devices, nuclear power equipment, and aerospace devices.

16. The hybrid liquid cooling system according to claim 4, wherein the hybrid liquid cooling system is applied in high-power chips, high-performance computing systems, power electronic devices, nuclear power equipment, and aerospace devices.

17. The hybrid liquid cooling system according to claim 5, wherein the hybrid liquid cooling system is applied in high-power chips, high-performance computing systems, power electronic devices, nuclear power equipment, and aerospace devices.

18. The hybrid liquid cooling system according to claim 6, wherein the hybrid liquid cooling system is applied in high-power chips, high-performance computing systems, power electronic devices, nuclear power equipment, and aerospace devices.

19. The hybrid liquid cooling system according to claim 7, wherein the hybrid liquid cooling system is applied in high-power chips, high-performance computing systems, power electronic devices, nuclear power equipment, and aerospace devices.

20. The hybrid liquid cooling system according to claim 8, wherein the hybrid liquid cooling system is applied in high-power chips, high-performance computing systems, power electronic devices, nuclear power equipment, and aerospace devices.
